(19) United States
(12) Patent Application Publication
(10) Pub. No.: US 2008/0108190 A1
(43) Pub. Date: May 8, 2008

(54) SiC MOSFETs and self-aligned fabrication methods thereof

(75) Inventor: Kevin Sean Matocha, Rexford, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/593,317

(22) Filed: Nov. 6, 2006

(51) Int. Cl. H01L 21/8234

(52) U.S. Cl. 438/197

(57) ABSTRACT

The present invention provides a method of fabricating a metal oxide semiconductor field effect transistor. The method includes the steps of forming a source region on a silicon carbide layer and annealing the source region. A gate oxide layer is formed on the source region and the silicon carbide layer. The method further includes providing a gate electrode on the gate oxide layer and disposing a dielectric layer on the gate electrode and the gate oxide layer. The method further includes etching a portion of the dielectric layer and a portion of the gate oxide layer to form sidewalls on the gate electrode. A metal layer is disposed on the gate electrode, the sidewalls and the source region. The method further includes forming a gate contact and a source contact by subjecting the metal layer to a temperature of at least about 800 degrees Celsius. The gate contact and the source contact comprise a metal silicide. The distance between the gate contact and the source contact is less than about 0.6 micrometers. A vertical SiC MOSFET is also provided.

### BACKGROUND

The invention relates generally to methods of fabricating silicon carbide based metal oxide field effect transistors (MOSFETs) and in particular to self-aligned methods of fabricating silicon carbide based MOSFETs.

Silicon carbide (SiC) is an attractive alternative to silicon for high voltage, high power applications due to the inherent material properties of SiC. For example, SiC exhibits a wide band gap and a high thermal conductivity that facilitates elevated temperature operation.

For certain devices such as, SiC vertical metal oxide field effect transistors (MOSFET), close packing of adjacent cells is desirable, to enhance on-resistance and switching performance. To increase cell packing density, the spacing between the gate and source contacts must be reduced. However, a reduction in the gate to source contact spacing typically reduces the manufacturable yield of SiC MOSFETs.

Therefore, it is desirable to provide a method that addresses these issues related to the spacing between gate and source contacts in vertical SiC MOSFETs. It is also desirable to increase the manufacturable yield of closely packed vertical MOSFET devices. Accordingly, a technique is needed to address one or more of the foregoing problems in the fabrication of SiC MOSFET devices.

### BRIEF DESCRIPTION

In one embodiment of the present invention, a method of fabricating a metal oxide semiconductor field effect transistor is provided. The method includes the steps of forming a source region on a silicon carbide layer and annealing the source region. A gate oxide layer is formed on the source region and the silicon carbide layer. The method further includes providing a gate electrode on the gate oxide layer and disposing a dielectric layer on the gate electrode and the gate oxide layer. The method further includes etching a portion of the dielectric layer and a portion of the gate oxide layer to form sidewalls on the gate electrode. A metal layer is disposed on the gate electrode, the sidewalls and the source region. The method further includes forming a gate contact and a source contact by subjecting the metal layer to a temperature of at least about 800 degrees Celsius. The gate contact and the source contact comprise a metal silicide. The distance between the gate contact and the source contact is less than about 0.6 micrometers.

According to embodiments of the present invention, a vertical SiC metal oxide semiconductor field effect transistor (MOSFET) is provided. The SiC MOSFET includes a silicon carbide layer having a source region. A gate oxide layer is disposed on the silicon carbide layer and extends over at least a portion of the source region. The MOSFET includes a gate electrode disposed on the gate oxide layer and a gate contact disposed on the gate electrode. The gate contact comprises metal silicide. The MOSFET further includes a source contact extending over at least a portion of the source region. The source contact comprises metal silicide, and the distance between the gate contact and the source contact is less than about 0.6 micrometers.

### DRAWINGS

These and other features, aspects, and advantages of the present invention will become better understood when the following detailed description is read with reference to the accompanying drawings in which like characters represent like parts throughout the drawings, wherein:

FIGS. 1-6 illustrate exemplary fabrication stages of a vertical SiC MOSFET, according to embodiments of the invention.

### DETAILED DESCRIPTION

It will be understood by those skilled in the art that “n-type” and “p-type” refer to the majority of charge carriers, which are present in a respective layer. For example, in n-type layers, the majority carriers are electrons, and in p-type layers, the majority carriers are holes (the absence of electrons). As used herein, n+ and n refer to higher (greater than 1×10¹⁸ cm⁻³) and lower (greater than 5×10¹⁶ cm⁻³) doping concentrations of the dopants, respectively.

As used herein, the term “about” should be understood to indicate plus or minus ten percent (±10%).

A MOSFET is a type of transistor that includes a gate, a drain and a source. The source and drain of a typical MOSFET are formed of a semiconducting substrate such as silicon. For SiC MOSFETs, the semiconducting substrate comprises SiC. The gate is separated from the substrate by an insulating layer. As will be appreciated, upon application of a voltage or an electric field across the gate, the source to drain current can be controlled. The current generated is then transferred from the substrate through respective gate and source contacts.

The performance of a MOSFET is to a large extent dependent on the gate and source contacts. It is desirable that the gate and source contacts are electrically and structurally stable during operation and also that they offer minimal ohmic resistance to passage of current. Moreover, by reducing the distance or spacing between the source contact and the gate contact in a MOSFET, the size of the MOSFET may be reduced and more of such MOSFETs may be packed within, for example, an integrated chip. Advantageously, the increase in packing density may enhance the on-resistance and switching performance of the device. The methods for enhancing the packing density may suffer from one or more limitations. For example, the methods for reducing the distance between the source contact and the gate contact may inadvertently cause the shorting of these contacts due to poor alignment.

Embodiments of the present invention addresses these and other needs and are described below in detail with reference to the accompanying drawings. The same reference numerals denote the same parts throughout the drawings.

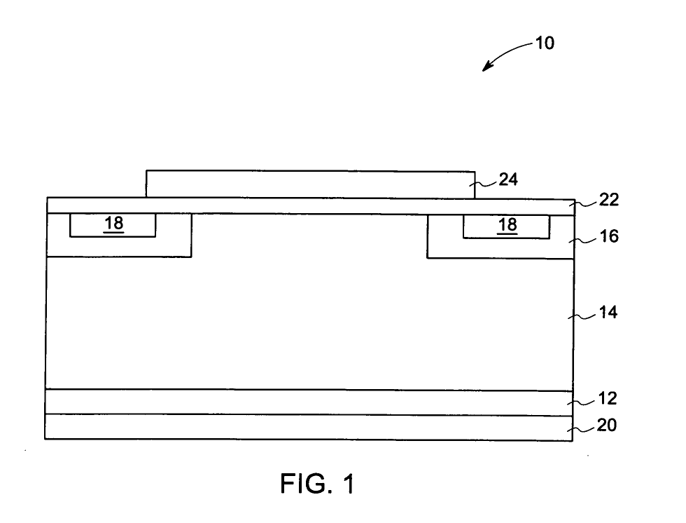

Turning now to the figures, FIGS. 1-6 illustrate fabrication stages of a vertical SiC MOSFET 10, according to embodiments of the present invention. FIG. 1 is a cross-sectional side view of a vertical SiC MOSFET 10. The SiC MOSFET 10 includes a semiconductor layer 12 having a drift region 14 disposed thereon. The semiconductor layer 12 may be a semiconductor substrate on which other materials are formed, disposed and/or patterned. Alternatively, semiconductor layer 12 may be an intermediate layer of a device being fabricated on an underlying substrate. The semiconductor layer 12 may be a semiconductor material such as, silicon, silicon carbide, aluminum nitride, sapphire, or gallium nitride, for example. Further, the semiconductor layer 12 may be a polytype of silicon carbide, such as 4H-SiC, or 6H-SiC polytypes. The semiconductor layer 12 may be p-type doped, or n-type doped or even undoped. In the illustrated embodiment, the semiconductor layer 12 is of 4H-SiC and is n-type doped. The semiconductor layer 12 may have a thickness of about 550 micrometers and a dopant concentration of about 5×10¹⁸ ions/cm³, for example. In certain embodiments, the thickness of the semiconductor layer 12 may be in a range of about 200 micrometers to about 600 micrometers. In some embodiments, the dopant concentration of the semiconductor layer 12 may be in a range of about 1×10¹⁸ ions/cm³ to about 1×10²¹ ions/cm³.

The drift region 14 is of silicon carbide. Further, the drift region 14 may be a polytype of silicon carbide, such as 4H-SiC, or 6H-SiC polytypes. In the illustrated example of the MOSFET 10 having an n+ doped source region, the drift region 14 is n-type doped with n-type dopants such as nitrogen, phosphorus, or any combinations thereof. As will be appreciated, for a MOSFET 10 having a p+ doped source region, the drift region 14 may be doped with p-type dopants including boron, aluminum, gallium, carbon, or any combinations thereof. The dopants may be introduced during the formation of the drift region 14, for example. In some embodiments, a deposition technique such as, chemical vapor deposition (CVD) may be performed to form the drift region 14. Alternatively, an epitaxial growth of the semiconductor layer 12 is performed to form the drift region 14, and the dopants are introduced during the epitaxial growth. The drift region 14 may have a doping concentration in a range of about 1×10¹⁴ ions/cm³ to about 1×10¹⁶ ions/cm³. In one embodiment, the drift region 14 is about 12 micrometers thick and is of 4H-SiC with an n-type doping level of about 9×10¹⁵ ions/cm³.

In the drift region 14, P-well regions 16 are formed. The P-well region 16, in one embodiment, is formed by ion implantation of p-type dopants such as boron, aluminum, gallium, carbon, or any combinations thereof in the drift region 14. As will be appreciated, the formation of p-well region 16 may involve a number of processing steps such as, masking the drift region 14 by a first mask, and patterning the first mask prior to ion implantation in the drift region 14. In one embodiment, the masking is by the application of a photoresist over the drift region 14. The applied photoresist is then patterned by forming openings, wherein the openings correspond to an area of the P-well region 16. Through the openings in the photoresist the p-type dopant ions are implanted in the drift region 14 to obtain the P-well regions 16. In one embodiment, subsequent to the formation of P-well region 16, the photoresist is removed. Alternatively, a second mask may be applied on the first mask prior to ion implantation to form a source region 18 in the P-well region 16. The implanted p-type dopants are then annealed at elevated temperatures to electrically activate the implanted ions. In one embodiment, the annealing temperature is greater than about 1100 degrees Celsius (° C.). In some embodiments, the annealing temperature is in a range of about 1100 degrees Celsius to about 1700 degrees Celsius. Typically, the concentration of the implanted ions in the P-well region 16 is greater than that of the drift region 14 to facilitate implantation of p-type dopants in the n-doped drift region 14. In one embodiment, the concentration of the p-type dopants in the P-well region 16 is greater than about 1×10¹⁶ ions/cm³. In certain embodiments, the concentration of the p-type dopants in the P-well region 16 is in a range of about 1×10¹⁶ ions/cm³ to about 5×10¹⁸ ions/cm³.

The n+ source region 18 is formed in the P-well regions 16. In one embodiment, a second mask is applied after the removal of the first mask and may include processes as described with reference to the first masking process. The n-type dopants are implanted in the P-well region 16 through the openings in the second mask, for example, in a method involving the masking technique. Example n-type dopants include nitrogen, phosphorus, or any combinations thereof. The n+ source region 18 has a dopant concentration greater than about the concentration of the p-type dopants in the P-well region 16. In some embodiments, the dopant concentration in the n+ source region 18 is greater than about 1×10¹⁸ ions/cm³. In certain embodiments, the dopant concentration in the n+ source region 18 is in a range of about 1×10¹⁸ ions/cm³ to about 1×10²¹ ions/cm³. Subsequent to the formation of the source region 18, the implanted n-type dopants are annealed at elevated temperature so as to activate the implanted ions. In one embodiment, the annealing temperature is greater than about 1650 degrees Celsius. In some embodiments, the annealing temperature is in a range of about 1200 degrees Celsius to about 1750 degrees Celsius.

A drain region 20 may be provided on a surface of the semiconductor layer 10 opposite to the drift region 14. In some embodiments, the drain region 20 forms part of the semiconductor layer 12 which is heavily n-type doped. The concentration of the dopants in the drain region 20, in some embodiments, is greater than about 1×10¹⁸ ions/cm³. In certain embodiments, the concentration of the dopants in the drain region 20 is in a range of about 1×10¹⁸ ions/cm³ to about 1×10²¹ ions/cm³.

A gate oxide layer 22 is disposed on the source region 18, the P-well regions 16 and on the drift region 14. The formation of the gate oxide layer 22, in one example, is through thermal oxidation of the drift region 14. In another example, a low temperature chemical vapor deposition (CVD) technique is used to form the gate oxide layer 22. The gate oxide layer comprises silicon dioxide (SiO₂), silicon nitride or other glass forming materials. Non-limiting examples of glass forming materials include borosilicate glass or phosphosilicate glass. Typical thickness of the gate oxide layer 22 is less than about 200 nanometers. In some embodiments, the thickness of the gate oxide layer 22 is in a range of about 20 nanometers to about 200 nanometers.

A gate electrode 24 is disposed on the gate oxide layer 22. Exemplary gate electrode 24 materials include metals and polysilicon. The deposition of the gate electrode 24, in one embodiment, is performed using physical vapor deposition (PVD) techniques such as sputtering or evaporation. Alternatively, a chemical vapor deposition technique may be utilized. The gate electrode 24 covers a portion of the gate oxide layer 22. The remaining uncovered portion of the gate oxide layer 22 corresponds to a future location of a source contact. Typically, the thickness of the gate electrode 24 is about 0.5 micrometers. In some embodiments, the thickness of the gate electrode 24 is in a range of about 0.1 micrometers to about 1.0 micrometer.

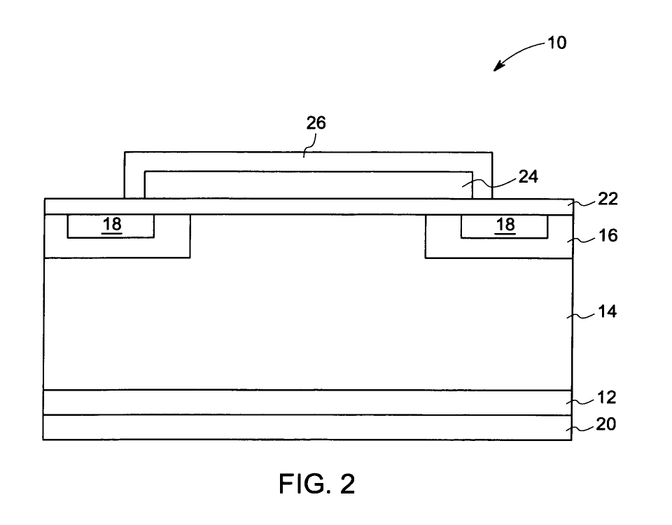

As shown in FIG. 2, a dielectric layer 26 is disposed on the gate electrode 24 and the gate oxide layer 22. The dielectric layer 26 forms a thin layer around the gate electrode 24 and may advantageously protect the gate electrode 24 from damages from subsequent processing steps. In exemplary embodiments, the dielectric layer 26 comprises silicon dioxide or silicon nitride. In one embodiment, the deposition of the dielectric layer 26 is through thermal oxidation of the gate electrode 24. Following thermal oxidation, the dielectric layer 26 is annealed at temperatures greater than about 1100 degrees Celsius. Alternatively, a chemical vapor deposition technique may be employed. The thickness of the dielectric layer 26 may play a part in determining the distance between a source contact and a gate contact. In some embodiments, the thickness of the dielectric layer 26 is greater than about 0.5 micrometers. In one embodiment, the thickness of the dielectric layer 26 is in a range of about 0.1 micrometers to about 1.0 micrometer.

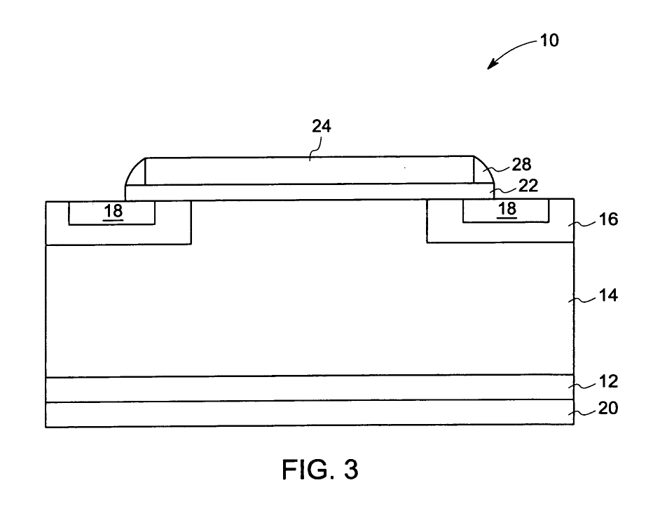

The dielectric layer 26 and the gate oxide layer 22 are then subjected to etching such that a portion of the gate oxide layer 22 and a portion of the dielectric layer 26 are removed so as to form sidewalls 28 on the gate electrode 24, as shown in FIG. 3. In one embodiment, the etching is performed using a dry etch process. In one embodiment, the dry etch is through a reactive ion etch (RIE) method. In the reactive ion etch method, etchants such as CF₄ and O₂ are used, which preferentially etches the gate oxide layer 24 and the dielectric layer 26 while the etchants CF₄ and O₂ have minimal action towards the drift region 14. The portion of the gate oxide layer 24 and the portion of the dielectric layer 26 are etched away to form the sidewalls 28. According to embodiments of the present invention, the width of the sidewalls 28 is advantageously used to control the distance between a gate contact and a source contact.

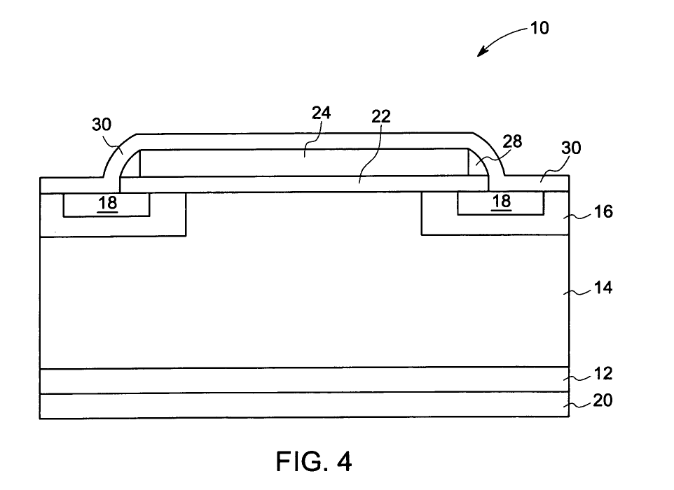

FIG. 4 depicts a metal layer 30 disposed on the gate electrode 24, the sidewalls 28 and over the P-well region 16 and the source region 18. In one embodiment, the deposition of metal layer 30 is through PVD techniques such as sputtering or evaporation. In another embodiment, the metal layer 30 is deposited using a chemical vapor deposition technique. In a particular embodiment, the metal layer comprises nickel. In other embodiments, the metal layer 30 comprises cobalt or titanium. The metal layer 30 is deposited as a thin layer. In some embodiments, the thickness of the metal layer 30 is in a range of about 25 nanometers to about 500 nanometers. In certain embodiments, the thickness of the metal layer 30 is in a range of about 25 nanometers to about 55 nanometers. In one particular embodiment, the thickness of the metal layer 30 is about 55 nanometers.

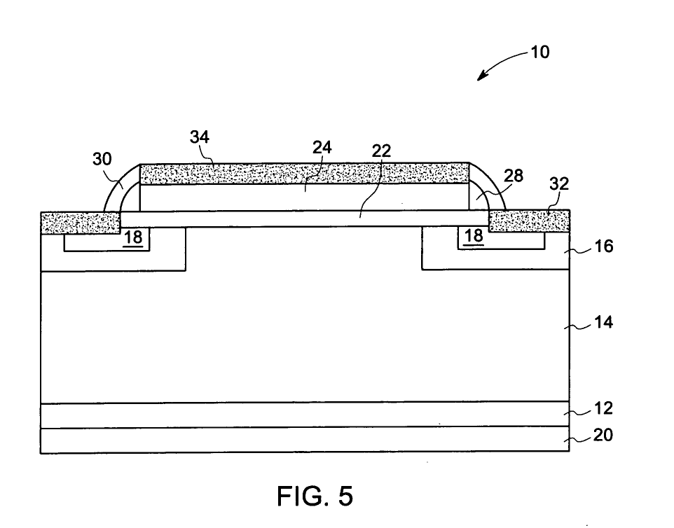

The metal layer 30 is then subjected to high temperature annealing to form metal silicide layers 32 and 34 (layers 32 and 34 are the future source and gate contacts, respectively), respectively, as shown in FIG. 5. The metal reacts with silicon to form the respective metal silicide. For example, when the metal layer 30 comprises nickel, then the layers 32 and 34 comprise nickel silicide. In other embodiments, the metal silicide comprises cobalt silicide or titanium silicide. The metal layer 30 in contact with the underlying silicon at the source region 18 reacts to form the metal silicide layer 32. Similarly, the metal layer 30 in contact with the underlying silicon at the gate electrode 24 form the metal silicide layer 32. As will be appreciated, the sidewalls 28 comprising the dielectric material, for example, silicon dioxide shows no activity towards the metal and hence there is no metal silicide formation on the sidewalls 28. According to embodiments of the present invention, the distance between the metal silicide layers 32 and 34 is to a large extent dependent on the width of the sidewalls 28. In one embodiment, the distance between the metal silicide layers 32 and 34 is less than about 0.6 micrometers. In some embodiments, the distance between the metal silicide layers 32 and 34 is in a range of about 0.1 micrometers to about 1.0 micrometer.

In one embodiment, the metal layer 30 is annealed at a temperature of at least about 800 degrees Celsius. In some embodiments, the annealing temperature is in a range of about 800 degrees Celsius to about 1100 degrees Celsius. In one example, the metal layer 30 is annealed at a temperature of about 1050 degrees Celsius for 3 minutes in nitrogen. Exemplary anneal times are in a range of about 1 minute to about 30 minutes. The composition of the metal silicide layers 32 and 34, and in turn the quality of the resultant ohmic contacts to a certain extent depends on the annealing temperature. Typically, nickel silicide contacts are formed at temperatures lower than about 700 degrees Celsius to avoid undesirable changes in the underlying layers. For example, high temperature annealing may result in diffusion of dopants from a source region to a substrate which may decrease the efficiency of the device.

According to embodiments of the invention, an annealing temperature of greater than about 800 degrees Celsius may result in a better contact than the contact formed at temperatures below about 700 degrees Celsius. Although, the applicant does not wish to be bound by any particular theory, it is believed that the high temperature anneal may form a metal silicide phase that may lower the ohmic resistance at the interface between the SiC and the metal silicide and hence may result in a better contact.

The metal silicide layers 32 and 34 may have a thickness of at least about 55 nanometers, in one embodiment. In some embodiments, the thickness of the metal silicide layers 32 and 34 is in a range of about 25 nanometers to about 500 nanometers.

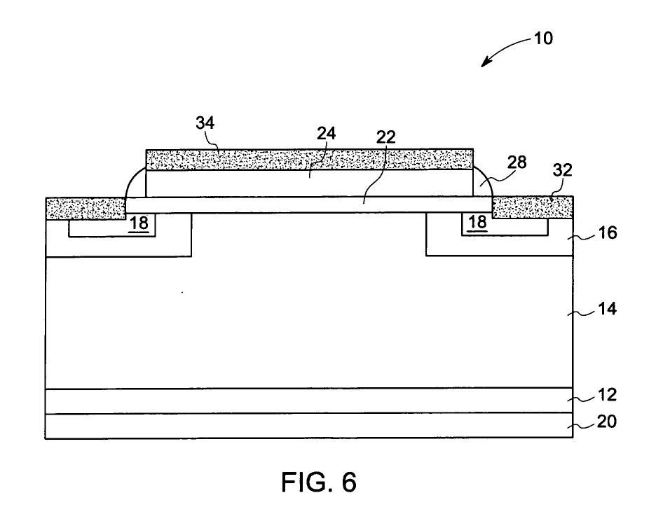

The remaining metal (that is on the sidewalls 28) is then etched to form the source contact 32 and the gate contact 34, respectively, as depicted in FIG. 6. The etching is through a wet-etching process that preferentially etches the metal while leaving the source contact 32 and the gate contact 34 behind.

The source contact 32 and the gate contact 34 are typically used to provide low resistance contacts for the source region 18 and the gate electrode 24. In one embodiment, at least one of the source contact 32 and the gate contact 34 has a contact resistivity of less than about 10⁻⁵ ohm/cm⁻². In some embodiments, at least one of the source contact 32 and the gate contact 34 has a contact resistivity in a range of about 10⁻³ ohm/cm⁻² to about 10⁻⁶ ohm/cm⁻².

The SiC vertical MOSFET 10 formed using embodiments of the present invention advantageously has a spacing of less than about 0.6 micrometers between the source contact and the gate contact. In some embodiments, the spacing between the source contact and the gate contact is in a range of about 0.1 micrometers to about 1.0 micrometer. Moreover, using self-aligned methods may provide a better alignment of the source contact and the gate contact with respect to the each other, and with the respect to the source region and the gate region, thus avoiding undesirable shorting effects that reduces the manufacturable yield of the MOSFETs.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of fabricating a Metal Oxide Semiconductor Field Effect Transistor (MOSFET) comprising the steps of:
forming a source region on a silicon carbide layer;
annealing the source region;
forming a gate oxide layer on the source region and the silicon carbide layer;
providing a gate electrode on the gate oxide layer;
disposing a dielectric layer on the gate electrode and the gate oxide layer;
etching a portion of the dielectric layer and a portion of the gate oxide layer to form sidewalls on the gate electrode;
disposing a metal layer on the gate electrode, the sidewalls and the source region; and
forming a gate contact and a source contact by subjecting the metal layer to a temperature of at least about 800° C., wherein the gate contact and the source contact comprise a metal silicide, and wherein a distance between the gate contact and the source contact is less than about 0.6 micrometers.

2. The method of claim 1, wherein forming the source region comprises ion implanting the silicon carbide layer.

3. The method of claim 1, wherein annealing the source region comprises subjecting the source region to a temperature in a range of about 1200° C. to about 1750° C.

4. The method of claim 1, wherein the gate oxide layer has a thickness of less than about 200 nm.

5. The method of claim 1, wherein forming the gate oxide layer comprises thermally oxidizing the silicon carbide layer.

6. The method of claim 1, wherein forming the gate oxide layer comprises depositing the gate oxide layer on the silicon carbide layer.

7. The method of claim 1, wherein the gate oxide layer comprises silicon dioxide, silicon nitride, or glass forming material.

8. The method of claim 1, wherein the gate electrode comprises polysilicon.

9. The method of claim 1, wherein the dielectric layer has a thickness in a range of about 0.1 micrometers to about 1.0 micrometer.

10. The method of claim 1, wherein the dielectric layer comprises silicon dioxide or silicon nitride.

11. The method of claim 1, wherein the gate electrode comprises polysilicon, and wherein disposing the dielectric layer comprises oxidizing the gate electrode.

12. The method of claim 1, wherein the metal layer comprises nickel.

13. The method of claim 1, wherein the metal layer comprises cobalt or titanium.

14. The method of claim 1, wherein the temperature to which the metal layer is subjected is in a range of about 800° C. to about 1100° C.

15. The method of claim 1, wherein forming the gate contact and the source contact comprises etching a plurality of portions of the metal layer disposed on the sidewalls.

16. The method of claim 1, wherein the distance between the gate contact and the source contact is in a range of about 0.1 micrometers to about 1.0 micrometer.

17. A vertical silicon carbide (SiC) Metal Oxide Semiconductor Field Effect Transistor (MOSFET) comprising:
a silicon carbide layer comprising a source region;
a gate oxide layer disposed on the silicon carbide layer and extending over at least a portion of the source region;
a gate electrode disposed on the gate oxide layer;
a gate contact disposed on the gate electrode, wherein the gate contact comprises metal silicide; and
a source contact extending over at least a portion of the source region, wherein the source contact comprises metal silicide, and wherein a distance between the gate contact and the source contact is less than about 0.6 micrometers.

18. The SiC MOSFET of claim 17, wherein the source region has a dopant concentration in a range of about 1×10¹⁸ ions/cm³ to about 1×10²¹ ions/cm³.

19. The SiC MOSFET of claim 17, wherein the gate oxide layer has a thickness of less than about 200 nm.

20. The SiC MOSFET of claim 17, wherein the metal silicide comprises nickel silicide.

21. The SiC MOSFET of claim 17, wherein the metal silicide comprises titanium silicide or cobalt silicide.

22. The SiC MOSFET of claim 17, wherein at least one of the gate contact and the source contact has a contact resistivity of less than about 10⁻⁵ ohm/cm².

23. The SiC MOSFET of claim 17, wherein the distance between the gate contact and the source contact is in a range of about 0.1 micrometers to about 1.0 micrometer.

24. The SiC MOSFET of claim 17, wherein the gate electrode comprises polysilicon, and wherein the gate oxide layer comprises silicon dioxide.
